(19) United States
(12) Patent Application Publication
(10) Pub. No.: US 2007/0236269 A1
(43) Pub. Date: Oct. 11, 2007

(54) Non-linear current mode digital to analog converter for controlling a current starved delay stage

(75) Inventor: Tandur Lakshmi Viswanathan, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/400,850

(22) Filed: Apr. 10, 2006

(51) Int. Cl. H03H 11/26

(52) U.S. Cl. 327/276

(57) ABSTRACT

In a method and system for providing a digitally programmable delay, a variable gain circuit is operable to receive an input. The input is multiplied by a selectable gain to provide an output. A controller is coupled to receive an input vector. The controller selects the selectable gain in response to the input vector. A delay circuit is operable to receive a signal input and provide a delayed signal output, where the delay is controlled by the output having the selectable gain. The delay circuit provides the delayed signal output having a substantially linear time delay as a function of the input vector.

### BACKGROUND

The present disclosure relates generally to electronic circuits, and more particularly to a system and method for providing an improved digitally programmable delay element.

Use of variable delay elements is common in delay locked loop (DLL) and phase locked loop (PLL) circuits. A technical paper entitled ‘A Digitally Programmable Delay Element: Design And Analysis’, authored by Mohammad Maymandi-Nejad and Manoj Sachdev, and published in IEEE Transactions On Very Large Scale Integration (VLSI) Systems, Volume 11, No. 5, October 2003, pages 871-878, which is incorporated herein by reference, describes a digitally programmable current starved delay element for use in variable delay applications.

FIGS. 1A and 1B illustrate waveforms of a transient response of a digitally programmable delay element, according to prior art. FIG. 1A shows a time delay for a series of voltage outputs (Y-axis) of the digitally programmable delay element, the voltage outputs corresponding to each combination of the input vector, according to prior art. Spacing between adjacent voltage output waveforms is non-uniform, indicating that the delay is substantially higher for lower current values compared to the delay for higher currents. FIG. 1B shows the delay (Y-axis) as a function of the 4-bit input vector (X-axis), according to prior art. The delay is a non-linear function of the 4-bit input vector. That is, as IBIAS current is varied linearly over the input range of the 16 codes varying from 0000 to 1111, there is a corresponding non-linear delay in the digitally programmable delay element.

Thus, many digitally programmable delay elements may be unable to provide a delay that exhibits a linear relationship with a value of a digitally programmable 4-bit or 5-bit input vector.

### SUMMARY

Applicant recognizes that a need exists to provide a method and system for providing an improved digitally programmable delay element having a linearly varying delay. Accordingly, it would be desirable to provide a delay element that is digitally programmable to vary linearly over an input range of the IBIAS current, absent the disadvantages found in the prior methods discussed above.

The foregoing need is addressed by the teachings of the present disclosure, which relates to a digitally programmable delay element having a linearly varying delay. According to one embodiment, in a method and system for providing a digitally programmable delay, a variable gain circuit is operable to receive an input. The input is multiplied by a selectable gain to provide an output. A controller is coupled to receive an input vector. The controller selects the selectable gain in response to the input vector. A delay circuit is operable to receive a signal input and provide a delayed signal output, where the delay is controlled by the output having the selectable gain. The delay circuit provides the delayed signal output having a substantially linear time delay as a function of the input vector.

In a particular aspect, a method for providing a linear delay includes receiving a bias current input and receiving an input vector. The input vector is programmable to multiply the bias current input by a selectable gain to generate a control current, where the control current causes the linear delay in the signal input. The selectable gain of the bias current input is selected in response to the input vector so as to provide the linear delay that varies linearly with the input vector. A delayed signal output having the linear delay is provided in response to the signal input and the control current.

Several advantages are achieved by the method and system according to the illustrative embodiments presented herein. The embodiments advantageously provide for an improved digitally programmable delay circuit having a linear delay. The amount of delay is controllable in a linear manner by varying the input vector. Use of bias current signals advantageously enables control signals to be communicated across longer distances. This advantageously facilitates control of the delay for strobe signals associated with many data transfer applications.

### BRIEF DESCRIPTION OF THE DRAWINGS

FIG. 1A described hereinabove, illustrates a time delay for a series of voltage outputs of a digitally programmable delay element, the voltage outputs corresponding to each combination of an input vector, according to prior art;

FIG. 1B described hereinabove, illustrates a delay as a function of a 4-bit input vector, according to prior art;

FIG. 2 illustrates a block diagram of an improved digitally programmable delay circuit, according to an embodiment;

FIG. 3A is a table to illustrate in a tabular form a relationship between an input vector and a selectable gain of the digitally programmable delay circuit described with reference to FIG. 2, according to an embodiment;

FIG. 3B illustrates a graphical relationship between a non-linear delay 330 introduced by a prior art delay circuit and a linear delay 340 of the digitally programmable delay circuit 200 described with reference to FIG. 2, according to an embodiment;

FIG. 3C shows a time delay for a series of voltage outputs of a digitally programmable delay circuit described with reference to FIG. 2, the voltage outputs corresponding to each combination of the input vector, according to an embodiment;

FIG. 4 is an illustrative circuit diagram of a delay locked loop (DLL) system, according to an embodiment; and

FIG. 5 is a flow chart illustrating a method for providing a digitally programmable linear delay, according to an embodiment.

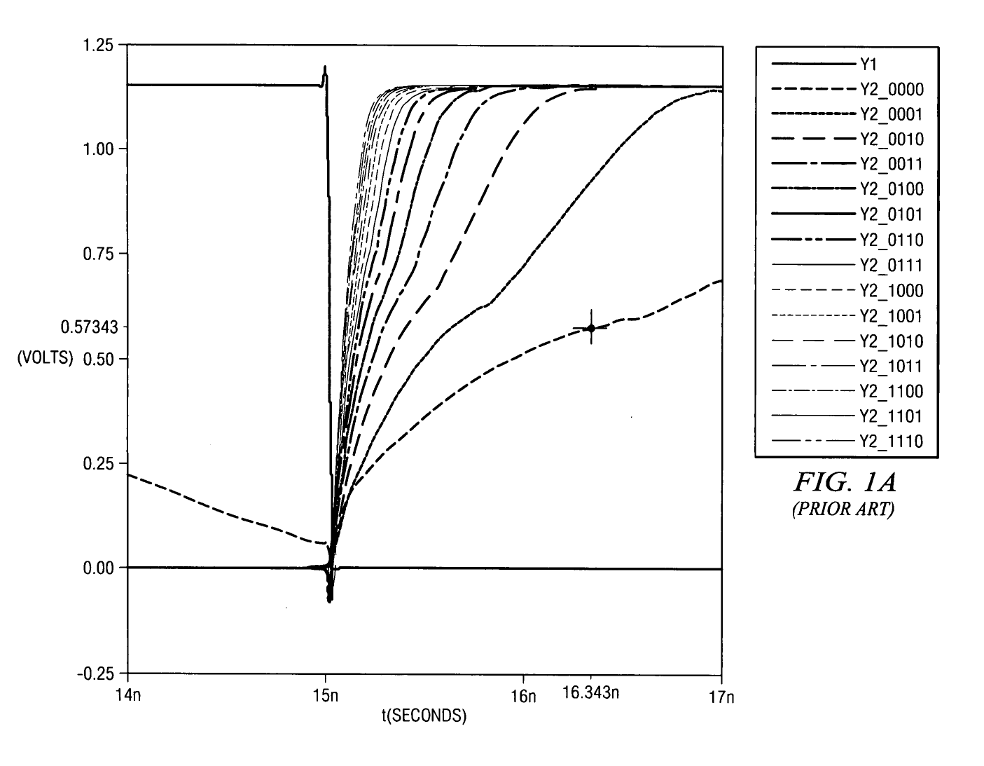

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip), firmware (including application specific integrated circuits and programmable chips) and/or software or a combination thereof, depending on the application requirements.

Many digitally programmable delay elements may be unable to provide a delay that exhibits a linear relationship with the I_{BIAS} current, where the I_{BIAS} current is digitally programmable by a 4-bit or 5-bit input vector. Therefore, a need exists to provide a method and system for providing an improved digitally programmable delay element having a linearly varying delay. According to one embodiment, in a method and system for providing a digitally programmable delay, a variable gain circuit is operable to receive an input. The input is multiplied by a selectable gain to provide an output. A controller is coupled to receive an input vector. The controller selects the selectable gain in response to the input vector. A delay circuit is operable to receive a signal input and provide a delayed signal output, where the delay is controlled by the output having the selectable gain. The delay circuit provides the delayed signal output having a substantially linear time delay as a function of the input vector.

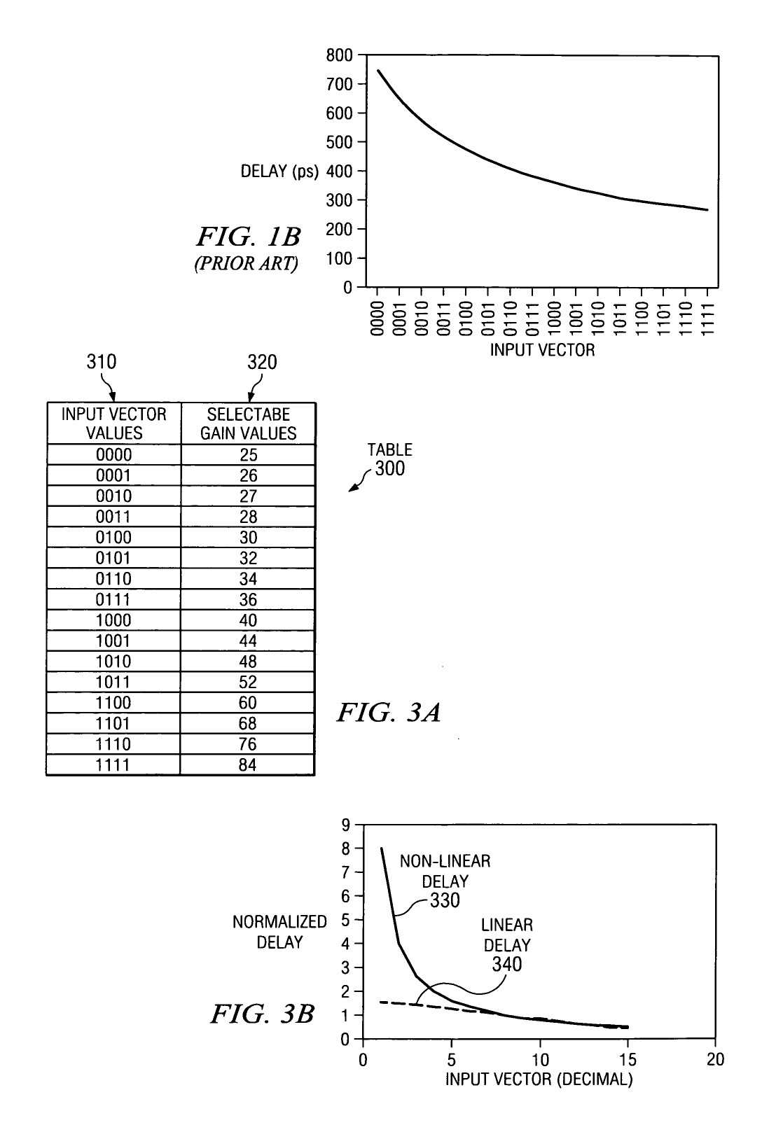

FIG. 2 illustrates a block diagram of an improved digitally programmable delay circuit 200, according to an embodiment. The digitally programmable delay circuit 200 includes a variable gain circuit 210, a controller 220 and a delay circuit 230. The variable gain circuit 210 is operable to receive an input 212, where the input 212 is multiplied by a selectable gain to provide an output 216. In an embodiment, the output 216 controls the operation of the delay circuit 230. The controller 220 is operable to receive an input vector 222. The controller selects the selectable gain in response to the input vector 222. In a particular embodiment, the input vector 222 may be a 4-bit or 5-bit digital input word. For example, a 4-bit input vector may vary from 0000 (lowest value) to 1111 (highest value). The mid-range value for the input vector may be a 0111 or a 1000.

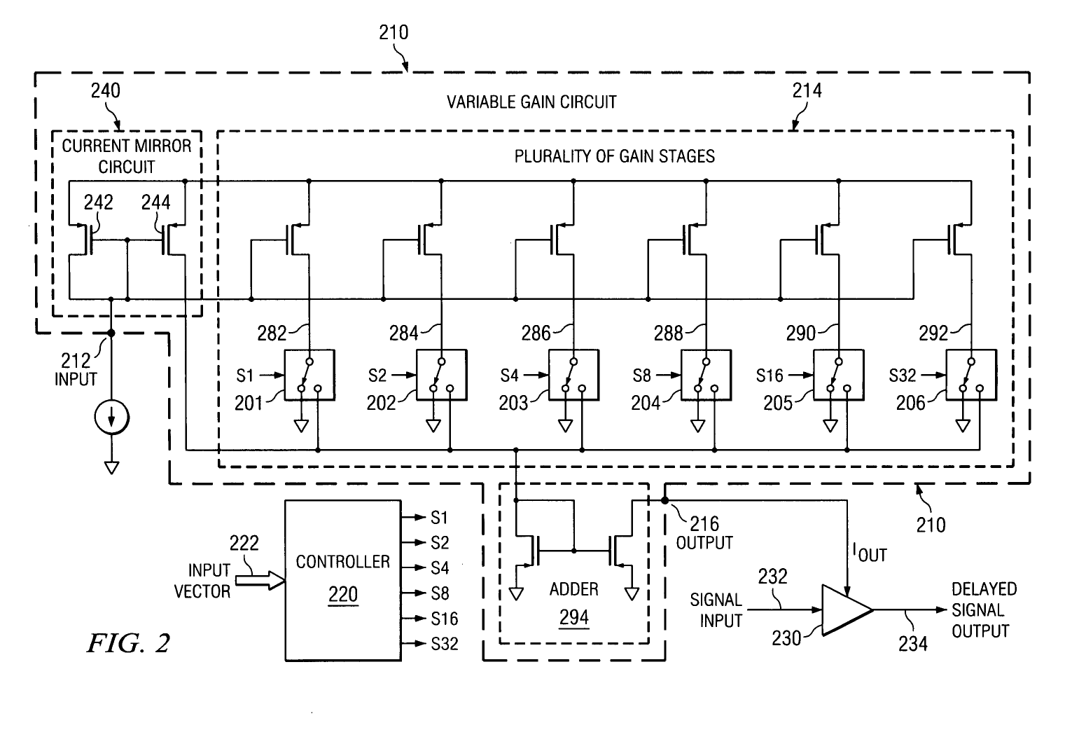

Value for the input vector 222 may be selected by a user for a particular delay application. Once selected the input vector 222 and hence the selected gain may remain fixed or static for the application. In an embodiment, the input vector 222 may be dynamically adjusted to vary the selected gain. The delay circuit 230 is operable to receive a signal input 232 and provide a delayed signal output 234. The delayed signal output 234 is controlled by the output 216 having the selectable gain. The delayed signal output 234 has a substantially linear time delay as a function of the input vector 222. Additional detail of the relationship between the selectable gain, the input vector 222 and the linear time delay of the delayed signal output 234 is described with reference to FIGS. 3A, 3B and 3C.

In a particular embodiment, the input 212 is received as a bias current input by a current mirror circuit 240 included in the variable gain circuit 210. Using bias current signals may advantageously enable control signals to be communicated over longer distances, especially compared to voltage signals. In a particular embodiment, the transistor 242 whose drain and gate are connected together is used in the current mirror configuration to enable the current gain involving all the transistors, 244, 282, 284, 286, 288, 290 and 292. In particular, the transistor 244 establishes the minimum gain. The current mirror circuit 240 supplies a substantially constant current to a load over a wide range of load resistances. In a particular embodiment, the variable gain circuit 210 includes a plurality of gain stages 214 with each stage having a corresponding selectable gain. In the depicted embodiment, shown are six gain stages coupled in parallel and numbered a first stage, a second stage, a third stage, a fourth stage, a fifth stage and a sixth stage, with each stage providing a corresponding gain of 2 raised to the power of N−1, where N corresponds to the stage number. Thus, the first stage has a gain of 1, the second stage has a gain of 2, the third stage has a gain of 4, the fourth stage has a gain of 8, the fifth stage has a gain of 16 and the sixth stage has a gain of 32.

Each stage is operable to receive the input 212 and provide a corresponding weighted output. Shown are weighted outputs 282, 284, 286, 288, 290 and 292 corresponding to each stage. Corresponding to each stage is a switch coupled in series with the weighted output. Shown are switches 201, 202, 203, 204, 205 and 206 corresponding to each one of the six stages. The switches 201, 202, 203, 204, 205 and 206 are individually controlled by the controller 220 in response to the input vector 222. The current outputs such as the bias current input, e.g., the input 212, and the weighted outputs, e.g., the weights outputs 282, 284, 286, 288, 290 and 292, are summed by an adder 294 to generate the output 216. Thus, the non-linear programming of the output current, e.g., the output 216, is achieved by proper combinations of the currents that are summed by the adder 294 included in the variable gain circuit 210 to form the control current for the delay circuit 230.

In a particular embodiment, the variable gain circuit 210, the controller 220 and the delay circuit 230 are included in at least one of a microprocessor, a digital signal processor, a radio frequency chip, a memory, a microcontroller and a system-on-a-chip or a combination thereof.

FIG. 3A is a Table 300 to illustrate in a tabular form a relationship between the input vector and the selectable gain of the digitally programmable delay circuit described with reference to FIG. 2, according to an embodiment. In the Table 300, the input vector 222 is a 4-bit digital input word having 16 values, shown in column 310. Column 320 shows exemplary values for the selectable gain corresponding to each input vector value. The Table 300 may be described to be a look up table since values for the selectable gain may be looked up that corresponds to a value of the input vector 222. The mid-range binary value of 1000 has a selectable gain of 40, which is selected to have a normalized value of 1. Thus, binary value of 0000 has a normalized value of 0.625 and a selectable gain value of 25 and binary value 1111 has a normalized value of 2.1 and a selectable gain value of 84. The non-linear variation in the selectable gain is selectable to cause a linear time delay of the delay output 234 as a function of the input vector 222. The particular values included in the Table 300 for the selectable gain may, however, vary depending on the delay application.

FIG. 3B illustrates a graphical relationship between a non-linear delay 330 introduced by a prior art delay circuit and a linear delay 340 of the digitally programmable delay circuit 200 described with reference to FIG. 2, according to an embodiment. The non-linear delay 330 increases to about 8× the nominal value at mid-range, e.g., at 1000 having a value of 8, for lower output currents. The linear delay 340 increases to about 1.5× the nominal value at mid-range for lower output currents.

FIG. 3C shows a time delay (X axis) for a series of voltage outputs (Y-axis) of the digitally programmable delay circuit 200 described with reference to FIG. 2, the voltage outputs corresponding to each combination of the input vector, according to an embodiment. Spacing between adjacent voltage output waveforms is substantially uniform, indicating that the time delay of the delay output 234 varies linearly with the input vector 222.

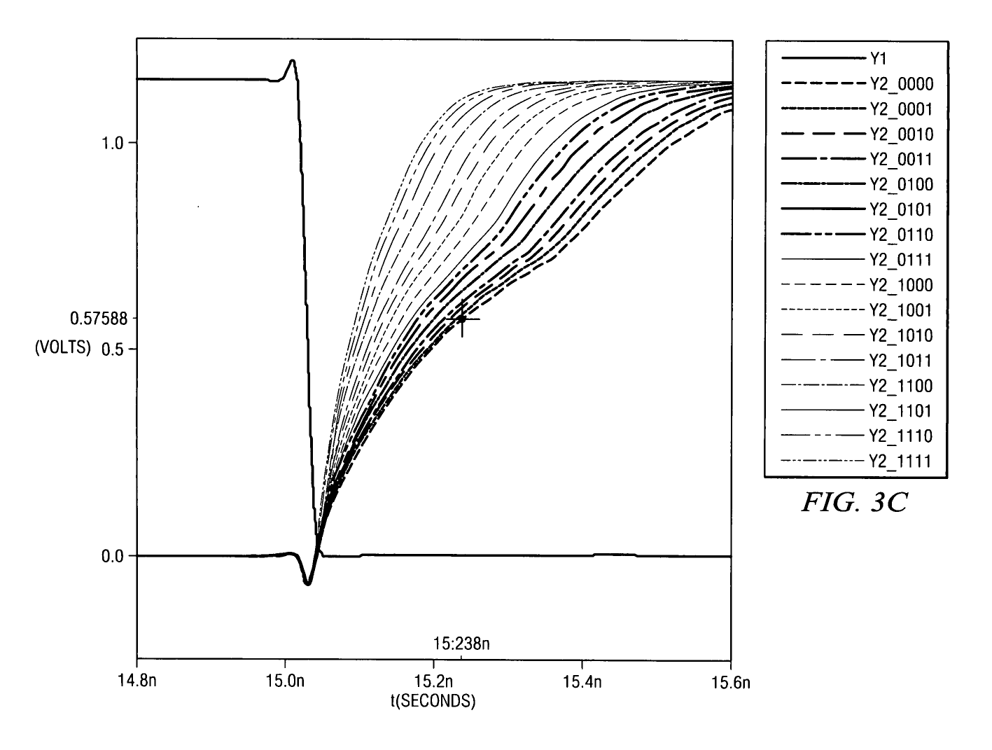

FIG. 4 is an illustrative circuit diagram of a delay locked loop (DLL) system 400, according to an embodiment. In the depicted embodiment, the DLL system 400 includes a master DLL 410 and a plurality of slave delay stages. For clarity, FIG. 4 depicts only a first slave delay stage 420 and a second slave delay stage 430. However, the DLL system 400 may include additional slave delay stages. The DLL system 400 may be used in memory transfer applications such as a double data rate (DDR) memory transfer. The Master DLL 410 includes a delay line having N stages which are phase locked to a system clock 402. The delay of each stage is controlled by a bias current I_{BIAS} 404. When the loop is locked each stage has a delay equal to T/N where T is the period of the clock 402.

In an exemplary, non-depicted embodiment, the slave delay stages 420 and 430 may be implemented with the digitally programmable delay circuit 200 described with reference to FIG. 2. The bias current I_{BIAS} 404 may also be provided to the slave delay stages 420 and 430. In a particular embodiment, the I_{BIAS} 404 is received by a current digital to analog converter (IDAC) 450. In an embodiment, the IDAC 450 includes the variable gain circuit 210 and the controller 220 described with reference to FIG. 2. The slave delay stages 420 and 430 may be used to linearly delay the strobe signals 406 and 408 associated with data transfer. In an embodiment, the number N of delay stages may be equal to either four or five leading to a nominal slave delay of T/4 or T/5 respectively.

In an embodiment, the digitally programmable delay circuit 200 is advantageously used to incrementally adjust the actual control current going into the delay circuit 230 by adjusting the digital control bits of the input vector 222. The number of slave delay stages may vary depending on the application. Each one of the strobe signals 406 and 408 may be generally associated with a particular number of data bits (such as 4, 8, 16 and similar others) that may be phase aligned. The strobe edges are delayed by the known fraction (¼ or ⅕) of the system clock period T to enable the capture of the data bits in each half period duration of the system clock 402.

In a particular embodiment, the DLL system 400 is included in at least one of a microprocessor, a digital signal processor, a radio frequency chip, a memory, a microcontroller and a system-on-a-chip or a combination thereof.

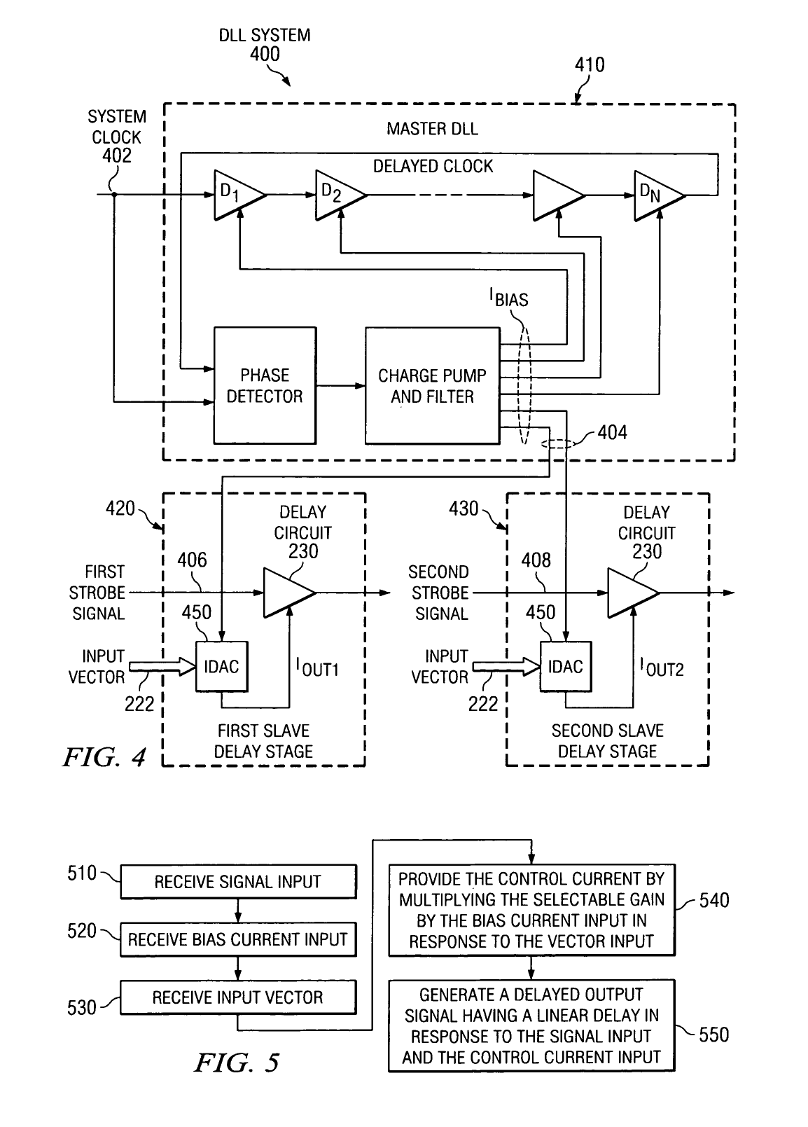

FIG. 5 is a flow chart illustrating a method for providing a digitally programmable linear delay, according to an embodiment. In a particular embodiment, the digitally programmable linear delay is provided by the digitally programmable delay circuit 200 described with reference to FIG. 2. At step 510, a signal input, e.g., the delay input 232, is received. At step 520, a bias current input, is received, e.g., received at the input 212. At step 530, an input vector, e.g., the input vector 222, is received. The input vector is programmable to multiply the bias current input by a selectable gain to generate a control current. The control current is used to control the delay circuit to cause the digitally programmable linear delay in the signal input. At step 540, the control current is provided by multiplying the selectable gain and the bias current input in response to the input vector. The selectable gain is selected, e.g., from the Table 300, to provide the digitally programmable linear delay that varies linearly with the input vector. At step 550, a delayed signal output having the linear delay in response to the signal input and the control current is provided.

Various steps described above may be added, omitted, combined, altered, or performed in different orders. For example, in a particular embodiment, steps 510, 520 and 530 may be combined into a single step to receive all inputs.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of the DLL system 400 having one or more devices, those of ordinary skill in the art will appreciate that the processes disclosed are capable of being implemented using hardware, software, and firmware components including systems-on-a-chip (SoC).

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A digitally programmable delay circuit comprising:
a variable gain circuit operable to receive an input, wherein the input is multiplied by a selectable gain to provide an output;
a controller coupled to receive an input vector, wherein the controller selects the selectable gain in response to the input vector; and
a delay circuit operable to receive a signal input and provide a delayed signal output, wherein the delayed signal output is controlled by the output, wherein the delayed signal output has a substantially linear time delay as a function of the input vector.

2. The circuit of claim 1, wherein the input is a bias current input received by a current mirror circuit.

3. The circuit of claim 1, wherein the variable gain circuit indudes:
a plurality of gain stages with each stage having a corresponding selectable gain.

4. The circuit of claim 3, wherein the input provided to each one of the plurality of gain stages is multiplied by the corresponding selectable gain to generate a corresponding weighted output.

5. The circuit of claim 3, wherein the plurality of gain stages include six stages numbered from 1 to 6, wherein each one of the six stages has the corresponding selectable gain equal to 2 to the power of N minus 1, wherein N corresponds to the stage number.

6. The circuit of claim 4, wherein each one of the weighted output is selectable by the controller, wherein the corresponding selectable gain of the selected ones of the weighted output are combined to match the selectable gain, wherein the selected ones of the weighted output are combined to provide the output.

7. The circuit of daim 1, wherein the controller selects the selectable gain from a look up table, wherein each combination of the input vector has a corresponding value for the selectable gain.

8. The circuit of claim 1, wherein a mid-range gain value for the selectable gain is defined as being equal to 1 corresponding to a mid-range value of the input vector, wherein a ratio of the selectable gain at lowest limit of the input vector to the mid-range gain value is equal to 0.625, wherein another ratio of the selectable gain at highest limit of the input vector to the mid-range gain value is equal to 2.1.

9. The circuit of claim 1, wherein the variable gain circuit, the controller and the delay circuit are included in at least one of a microprocessor, a digital signal processor, a radio frequency chip, a memory, a microcontroller and a system-on-a-chip or a combination thereof.

10. The circuit of claim 1, wherein the delay circuit is a current starved delay stage.

11. The circuit of claim 1, wherein the output having the selectable gain is a current output.

12. A method for providing a digitally programmable linear delay, the method comprising:
receiving a signal input;
receiving a bias current input;
receiving an input vector, wherein the input vector is programmable to multiply the bias current input by a selectable gain to generate a control current, the control current causing the linear delay in the delay input;
providing the control current by multiplying the selectable gain and the bias current input in response to the input vector, wherein the selectable gain is selected to provide the digitally programmable linear delay that varies linearly with the input vector;
providing a delayed signal output having the linear delay in response to the signal input and the control current.

13. In the method of claim 12, wherein the selectable gain is selected from a look up table, wherein each combination of the input vector has a corresponding value for the selectable gain.

14. In the method of claim 12, wherein a mid-range gain value for the selectable gain is defined as being equal to 1 corresponding to a mid-range value of the input vector, wherein a ratio of the selectable gain at lowest limit of the input vector to the mid-range gain value is equal to 0.625, wherein another ratio of the selectable gain at highest limit of the input vector to the mid-range gain value is equal to 2.1.

15. In the method of claim 12, wherein the digitally programmable linear delay is provided by at least one of a microprocessor, a digital signal processor, a radio frequency chip, a memory, a microcontroller and a system-on-a-chip or a combination thereof.

16. In the method of claim 12, wherein the input vector has at least one of a fixed value and a dynamic value.

17. A delay locked loop (DLL) comprising:
a master DLL loop operable to receive a clock input and provide current bias outputs; and
a plurality of slave delay stages, wherein each one of the plurality of slave delay stages receives a strobe input and provides a delayed strobe output, wherein each one of the plurality of slave delay stages receives one of the current bias outputs and an input vector to provide a delay for the delayed strobe output as a linear function of the input vector, wherein each one of the plurality of slave delay stages includes:
a variable gain circuit operable to receive the one of the bias current outputs, wherein the one of the bias current outputs is multiplied by a selectable gain to provide an output current to control the delay;
a controller coupled to receive the input vector, wherein the controller selects the selectable gain in response to the input vector.

18. The DLL of claim 17, wherein the master DLL loop includes:
a delay line with N stages, wherein each stage is locked to the clock input, wherein each stage has a stage delay controlled by the one of the current bias outputs, wherein the stage delay is equal to T divided by N, wherein T is a time period of the clock input.

19. The DLL of claim 17, wherein the variable gain circuit includes:
a plurality of gain stages with each stage having a corresponding selectable gain.

20. The DLL of claim 19, wherein the one of the current bias outputs provided to each one of the plurality of gain stages is multiplied by the corresponding selectable gain to generate a corresponding weighted output.

21. The DLL of claim 17, wherein the master DLL loop and the plurality of slave delay stages are included in at least one of a microprocessor, a digital signal processor, a radio frequency chip, a memory, a microcontroller and a system-on-a-chip or a combination thereof.
